(19) United States
(12) Patent Application Publication
(10) Pub. No.: US 2011/0248606 A1
(43) Pub. Date: Oct. 13, 2011

(54) RESONATOR ELEMENT, RESONATOR, AND PIEZOELECTRIC DEVICE

(75) Inventor: Akinori YAMADA, Ina (JP)

(73) Assignee: SEIKO EPSON CORPORATION, Tokyo (JP)

(21) Appl. No.: 13/080,902

(22) Filed: Apr. 6, 2011

(30) Foreign Application Priority Data
Apr. 13, 2010 (JP) 2010-092616

(51) Int. Cl. H01L 41/083; H01L 41/04

(52) U.S. Cl. 310/361; 310/367

(57) ABSTRACT

A resonator element includes: a laminate formed by laminating a plurality of piezoelectric substrates in which thickness-shear vibration occurs.

### BACKGROUND

1. Technical Field

The present invention relates to a resonator element, a resonator, and a piezoelectric device.

2. Related Art

As a resonator such as a crystal resonator included in a piezoelectric device such as a crystal oscillator, those using thickness-shear vibration are known (for example, refer to JP-A-2008-263387).

Such resonators include, for example, as disclosed in JP-A-2008-263387, a resonator element configured using a single piezoelectric substrate having thickness-shear vibration as the main vibration. In addition, the thickness-shear vibration is excited by applying a voltage to the piezoelectric substrate in the thickness direction thereof.

In addition, in the resonator disclosed in JP-A-2008-263387, the resonator element having a so-called mesa-shaped structure is used to trap the thickness-shear vibration and improve the Q value. As a result, the CI value (Crystal Impedance) is reduced.

However, in the structure described above according to the related art, in order to manufacture the thickness-shear resonator element that vibrates at a particular frequency, those having a particular thickness corresponding to the frequency of the piezoelectric substrate between a pair of excitation electrodes have to be used. Therefore, there is a limitation on the magnitude of an electric field that can be generated between the excitation electrodes. As a result, it is difficult to sufficiently reduce the CI value.

### SUMMARY

An advantage of some aspects of the invention is to provide a resonator element, a resonator, and a piezoelectric device capable of effectively exciting thickness-shear vibration while suppressing vibration other than the thickness-shear vibration.

The invention can be implemented as the following embodiment or application examples.

### Application Example 1

According to this application example of the invention, there is provided a resonator element including: a laminate formed by laminating a plurality of piezoelectric substrates in which thickness-shear vibration occurs.

Accordingly, the thickness of each of the piezoelectric substrates can be reduced, and displacement of the thickness-shear vibration of the entire resonator element can be increased while suppressing a voltage applied to each of the piezoelectric substrates. Accordingly, the thickness-shear vibration can be effectively excited while suppressing vibration other than the thickness-shear vibration.

### Application Example 2

In the resonator element according the application example of the invention, it is preferable that the laminate include: a first piezoelectric substrate in which thickness-shear vibration occurs; and a second piezoelectric substrate which is joined to one surface of the first piezoelectric substrate and in which thickness-shear vibration occurs in the same direction as that of the first piezoelectric substrate.

Accordingly, the displacement of the thickness-shear vibration of the entire resonator element can be increased.

### Application Example 3

In the resonator element according to the application example of the invention, it is preferable that the first and second piezoelectric substrates be configured so that thickness-shear vibration occurs therein in the same direction as a voltage that causes joined surfaces thereof to have the same polarity is applied in thickness directions thereof.

Accordingly, with a relatively simple configuration in which the first and second piezoelectric substrates are joined with an electrode layer interposed therebetween, thickness-shear vibration occurs in the first and second piezoelectric substrates in the same direction. In addition, the loss of the thickness-shear vibration between the first and second piezoelectric substrates can be reduced.

### Application Example 4

In the resonator element according to the application example of the invention, it is preferable that the first and second piezoelectric substrates be joined with an electrode layer interposed therebetween.

Accordingly, a voltage can be applied to the first and second piezoelectric substrates so that the joined surfaces therebetween have the same polarity.

### Application Example 5

In the resonator element according to the application example of the invention, it is preferable that at least one of the first and second piezoelectric substrates be made of a quartz crystal.

Accordingly, the thickness-shear vibration can be excited with desired vibration characteristics and high precision.

### Application Example 6

In the resonator element according to the application example of the invention, it is preferable that each of the first and second piezoelectric substrates be made of a quartz crystal.

Accordingly, the thickness-shear vibration can be excited with desired vibration characteristics and high precision.

### Application Example 7

In the resonator element according to the application example of the invention, it is preferable that the quartz crystal be a quartz-crystal rotated Y plate.

Accordingly, the thickness-shear vibration can be effectively excited in each of the first and second piezoelectric substrates.

### Application Example 8

In the resonator element according to the application example of the invention, it is preferable that a cut angle of the quartz crystal be any of an AT cut, a BT cut, and an SC cut.

Accordingly, the thickness-shear vibration can be effectively excited in each of the first and second piezoelectric substrates.

### Application Example 9

In the resonator element according to the application example of the invention, it is preferable that the first and second piezoelectric substrates be made of the quartz crystals having the same cut angle, and a crystal axis of the second piezoelectric substrate be the same direction as a crystal axis rotated with respect to the first piezoelectric substrate around a Y′ axis or a Z′ axis by 180°.

Accordingly, a voltage is applied so that the joined surfaces of the first and second piezoelectric substrates have the same polarity, and thus the thickness-shear vibration that occurs in the same direction in the first and second piezoelectric substrates is excited.

### Application Example 10

In the resonator element according to the application example of the invention, it is preferable that the laminate include a third piezoelectric substrate which is joined to the opposite surface of the second piezoelectric substrate to that of the first piezoelectric substrate and in which thickness-shear vibration occurs in the same direction as those of the first and second piezoelectric substrates.

Accordingly, the voltage applied to each of the piezoelectric substrates can further be suppressed, and the displacement of the thickness-shear vibration of the entire resonator element can be increased. Accordingly, the thickness-shear vibration can be effectively excited while further suppressing vibration other than the thickness-shear vibration.

### Application Example 11

According to this application example of the invention, there is provided a resonator including: the resonator element according to the above application example of the invention; and a package which accommodates the resonator element.

Accordingly, it is possible to provide the resonator capable of effectively exciting thickness-shear vibration while suppressing vibration other than the thickness-shear vibration.

### Application Example 12

According to this application example of the invention, there is provided a piezoelectric device including the resonator according to the above application example of the invention.

Accordingly, it is possible to provide the piezoelectric device capable of effectively exciting thickness-shear vibration while suppressing vibration other than the thickness-shear vibration.

### BRIEF DESCRIPTION OF THE DRAWINGS

The invention will be described with reference to the accompanying drawings, wherein like numbers reference like elements.

FIG. 1 is a top view illustrating a piezoelectric device (resonator) according to a first embodiment of the invention.

FIG. 2 is a cross-sectional view of the piezoelectric device illustrated in FIG. 1.

FIG. 3 is a schematic diagram for explaining an operation of a resonator element included in the piezoelectric device illustrated in FIG. 2.

FIG. 4 is a diagram for explaining a first example of a case where a first piezoelectric substrate and a second piezoelectric substrate included in the resonator element illustrated in FIG. 3 are made of AT-cut quartz crystals.

FIG. 5 is a diagram for explaining a second example of the case where the first piezoelectric substrate and the second piezoelectric substrate included in the resonator element illustrated in FIG. 3 are made of AT-cut quartz crystals.

FIG. 6 is a cross-sectional view of a resonator element included in a piezoelectric device according to a second embodiment of the invention.

FIG. 7 is a cross-sectional view of a resonator element included in a piezoelectric device according to a third embodiment of the invention.

FIG. 8 is a cross-sectional view of a resonator element included in a piezoelectric device according to a fourth embodiment of the invention.

FIG. 9 is a cross-sectional view of a resonator element included in a piezoelectric device according to a fifth embodiment of the invention.

FIG. 10 is a cross-sectional view of a resonator element included in a piezoelectric device according to a sixth embodiment of the invention.

### DESCRIPTION OF EXEMPLARY EMBODIMENTS

Hereinafter, as an example of a piezoelectric device according to the invention, a piezoelectric resonator and a piezoelectric device having an electronic component attached will be described in detail according to embodiments illustrated in the accompanying drawings.

### First Embodiment

First, a first embodiment of the invention will be described.

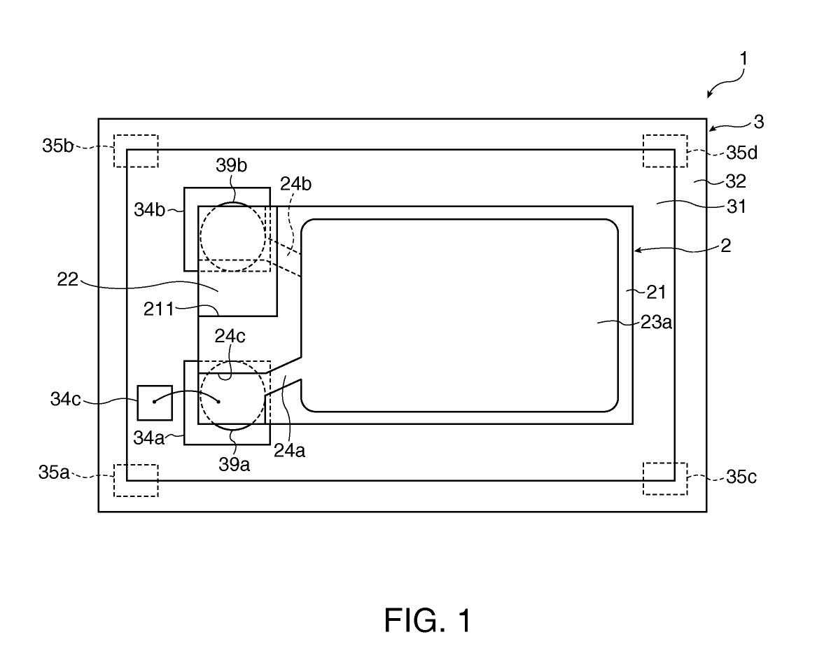

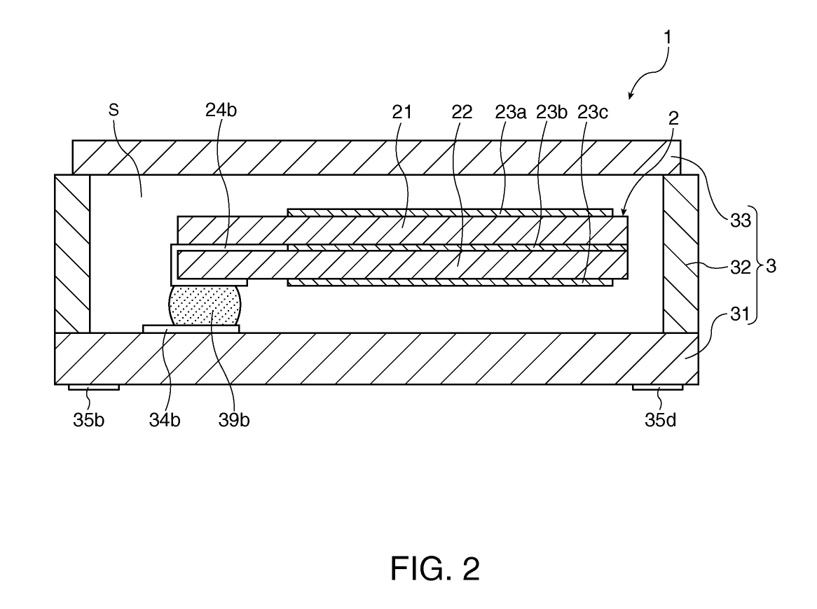

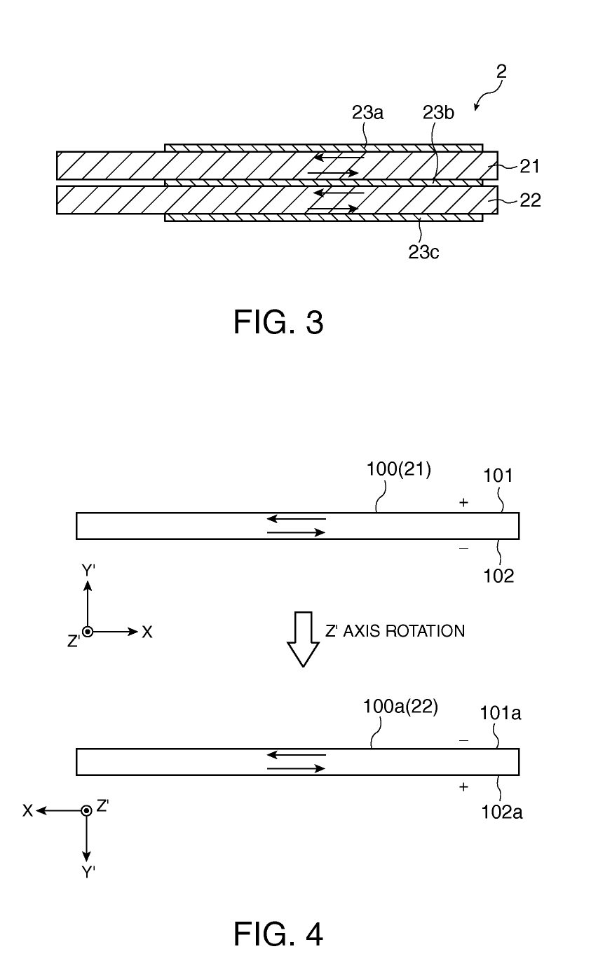

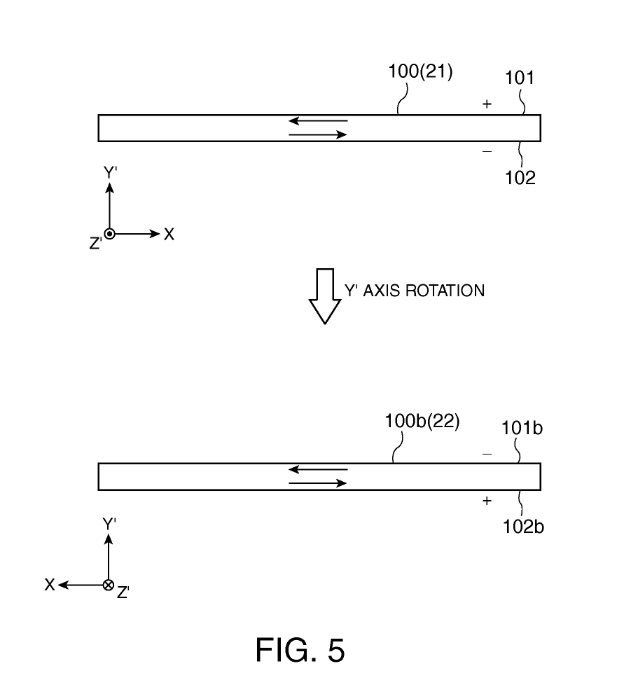

FIG. 1 is a top view illustrating a piezoelectric device (resonator) according to the first embodiment of the invention. FIG. 2 is a cross-sectional view of the piezoelectric device illustrated in FIG. 1. FIG. 3 is a schematic diagram for explaining an operation of a resonator element included in the piezoelectric device illustrated in FIG. 2. FIG. 4 is a diagram for explaining a first example of a case where a first piezoelectric substrate and a second piezoelectric substrate included in the resonator element illustrated in FIG. 3 are made of AT-cut quartz crystals. FIG. 5 is a diagram for explaining a second example of the case where the first piezoelectric substrate and the second piezoelectric substrate included in the resonator element illustrated in FIG. 3 are made of AT-cut quartz crystals. In addition, in the following description, for the convenience of description, the upper side in FIG. 2 is referred to as “upper”, the lower side is referred to as “lower”, the right side is referred to as “right”, the left side is referred to as “left”.

The resonator illustrated in FIG. 1 has a resonator element 2 and a package (housing) 3 accommodating this.

Hereinafter, each component of the resonator will be sequentially described in detail.

First, the resonator element 2 will be described.

The resonator element (piezoelectric resonator element) 2 has, as illustrated in FIG. 1 or 2, a first piezoelectric substrate 21 and a second piezoelectric substrate 22 having longitudinal shapes, an excitation electrode 23a and a connection electrode 24a provided on the upper surface of the first piezoelectric substrate 21, an excitation electrode 23b and a connection electrode 24b provided between the first and second piezoelectric substrates 21 and 22, and an excitation electrode 23c and a connection electrode 24c provided on the lower surface of the second piezoelectric substrate 22.

A voltage (electric field) is applied to each of the first and second piezoelectric substrates 21 and 22 in the thickness direction thereof, so that thickness-shear vibration is excited as the main vibration.

Particularly, as illustrated in FIG. 3, the first and second piezoelectric substrates 21 and 22 are configured so that thickness-shear vibration occurs therein in the same direction. In other words, the first and second piezoelectric substrates 21 and 22 are configured so that the opposed surfaces (joined surfaces) thereof displace in the opposite directions and thus result in thickness-shear vibration.

The resonator element 2 has a laminate formed by laminating a plurality of the piezoelectric substrates in which thickness-shear vibration occurs, so that the thicknesses of the first piezoelectric substrate 21 between the pair of the excitation electrodes 23a and 23b and the second piezoelectric substrate 22 between the pair of the excitation electrodes 23b and 23c can be reduced compared to those according to the related art. Therefore, even though a voltage applied to each piezoelectric substrate is suppressed, the displacement of thickness-shear vibration of the entire resonator element 2 can be increased by generating an electric field needed between the excitation electrodes which form a pair. Accordingly, thickness-shear vibration can be effectively excited while suppressing vibration other than the thickness-shear vibration.

More specifically, the first and second piezoelectric substrates 21 and 22 are joined with the excitation electrode 23b interposed therebetween which is an electrode layer that will be described later in detail. Accordingly, the second piezoelectric substrate 22 is joined to one surface of the first piezoelectric substrate 21.

Therefore, in this embodiment, a voltage that causes the joined surfaces (the surfaces of the opposed sides) of the first and second piezoelectric substrates 21 and 22 to have the same polarity is applied to each of the first and second piezoelectric substrates 21 and 22 in the thickness direction, so that thickness-shear vibration occurs therein in the same direction.

Accordingly, with a relatively simple configuration in which the first and second piezoelectric substrates 21 and 22 are joined with the excitation electrode 23b (electrode layer) interposed therebetween, thickness-shear vibration occurs in the first and second piezoelectric substrates 21 and in the same direction. In addition, the loss of the thickness-shear vibration between the first and second piezoelectric substrates 21 and 22 can be reduced.

The first and second piezoelectric substrates 21 and 22 are each made of a piezoelectric material. Examples of the piezoelectric material include a quartz crystal, lithium tantalate, lithium niobate, lithium borate, and barium titanate. Particularly, as the piezoelectric material, a quartz crystal is preferable.

When at least one of the first and second piezoelectric substrates 21 and 22 is made of a quartz crystal, thickness-shear vibration can be excited with desired vibration characteristics and high precision.

Particularly, when the first and second piezoelectric substrates 21 and 22 are each made of a quartz crystal, thickness-shear vibration can be excited with desired vibration characteristics and higher precision.

In the case where the first and second piezoelectric substrates 21 and 22 are each made of a quartz crystal, it is preferable that a quartz-crystal rotated Y plate be used as the quartz crystal. Accordingly, thickness-shear vibration can be effectively excited in the first and second piezoelectric substrates 21 and 22.

In addition, in the case where the first and second piezoelectric substrates 21 and 22 are each made of a quartz crystal, it is preferable that the cut angle of the quartz crystal be any of an AT cut, a BT cut, and an SC cut. Accordingly, thickness-shear vibration can be effectively excited in the first and second piezoelectric substrates 21 and 22.

In addition, when the first and second piezoelectric substrates 21 and 22 are configured as piezoelectric quartz crystal plates with the same cut angle, it is preferable that in order to cause the two piezoelectric substrates to have the same phase in thickness-shear vibration even though the direction of an electric field applied to the first piezoelectric substrate 21 is opposite to that of the second piezoelectric substrate 22, the front and back direction or the left and right direction of the second piezoelectric substrate 22 be reversed with respect to that of the first piezoelectric substrate 21. That is, the crystal axis of the second piezoelectric substrate 22 be the same direction as a crystal axis rotated with respect to the first piezoelectric substrate 21 around the Y′ axis or the Z′ axis by 180°.

For example, in a case where the first and second piezoelectric substrates 21 and 22 are configured using plate-like quartz crystals in which a cut angle is an AT cut (hereinafter, referred to as an AT plate), as illustrated in FIG. 4, a lower surface 102 of an AT plate 100 which is a non-rotation AT plate and an upper surface 101a of an AT plate 100a which is configured by rotating a non-rotation AT plate around the Z′ axis by 180° are joined with the excitation electrode 23b interposed therebetween, thereby obtaining the first piezoelectric substrate 21 configured with the AT plate 100 and the second piezoelectric substrate 22 configured with the AT plate 100a. In addition, as a voltage is applied to the AT plate 100 in the thickness direction (Y′ axis direction), thickness-shear vibration occurs therein in the X axis direction.

In addition, as illustrated in FIG. 5, the lower surface 102 of the AT plate 100 which is a non-rotation AT plate and an upper surface 101b of an AT plate 100b which is configured by rotating a non-rotation AT plate around the Y′ axis by 180° are joined with the excitation electrode 23b interposed therebetween, thereby obtaining the first piezoelectric substrate 21 configured with the AT plate 100 and the second piezoelectric substrate 22 configured with the AT plate 100b.

As a voltage is applied so that the joined surfaces of the first and second piezoelectric substrates 21 and 22 have the same polarity as described above, thickness-shear vibration that occurs in the same direction in the first and second piezoelectric substrates 21 and 22 is excited.

In addition, as illustrated in FIGS. 4 and 5, when the first and second piezoelectric substrates 21 and 22 are configured using the quartz crystals having the same cut angle, the frequency of the thickness-shear vibration of the resonator element 2 having the two AT plates joined is half the frequency of thickness-shear vibration that occurs in a single AT plate.

In other words, when the frequency of the thickness-shear vibration of the resonator element 2 is assumed to be F Hz, two AT plates in which thickness-shear vibration occurs at 2F Hz may be used.

The average thickness of the first and second piezoelectric substrates 21 and 22 is determined depending on the drive frequency of the resonator element 2 and is not particularly limited. Therefore, the first and second piezoelectric substrates 21 and 22 may have the same thickness or difference thicknesses. However, it is preferable that the thickness of one of the first and second piezoelectric substrates 21 and 22 be an integer multiple of that of the other. Accordingly, thickness-shear vibration may occur effectively in the entire resonator element 2 at a desired frequency.

As illustrated in FIGS. 1 and 2, the excitation electrode 23a is provided to cover the central portion of the upper surface of the first piezoelectric substrate 21. In addition, in the upper surface of the first piezoelectric substrate 21, at a portion which is a left end portion in the longitudinal direction and also one end portion in the lateral direction, the connection electrode 24a is provided, and the excitation electrode 23a and the connection electrode 24a are electrically connected to each other.

In addition, the excitation electrode 23b is provided to cover the central portions of the lower surface of the first piezoelectric substrate 21 and the upper surface of the second piezoelectric substrate 22. In addition, in the upper surface of the second piezoelectric substrate 22, at a portion which is the left end portion in the longitudinal direction and also the other end portion in the lateral direction, the connection electrode 24b is provided, and the excitation electrode 23b and the connection electrode 24b are electrically connected to each other. In addition, the connection electrode 24b is wrapped around the side surface and the lower surface of the second piezoelectric substrate 22 from the upper surface thereof.

In addition, the excitation electrode 23c is provided to cover the central portion of the lower surface of the second piezoelectric substrate 23. In addition, in the lower surface of the second piezoelectric substrate 22, at the portion which is the left end portion in the longitudinal direction and also one end portion in the lateral direction (the end portion on the opposite side to the connection electrode 24b), the connection electrode 24c is provided, and the excitation electrode 23c and the connection electrode 24c are electrically connected to each other.

The excitation electrodes 23a, 23b, and 23c are formed to have overlapping regions. In addition, when an electric field is applied to the excitation electrodes 23a, 23b, and 23c via the connection electrodes 24a, 24b, and 24c while the connection electrodes 24a and 24c have the same polarity, due to the inverse piezoelectric effect of the piezoelectric material, thickness-shear vibration occurs in the first and second piezoelectric substrates 21 and 22 at a certain frequency (resonant frequency) as described above. In addition, as the first and second piezoelectric substrates 21 and 22 vibrate, a voltage is generated at a certain frequency between the excitation electrodes 23a and 23b and between the excitation electrodes 23b and 23c due to the piezoelectric effect of the piezoelectric material. Using the characteristics, the piezoelectric device 1 may generate an electric signal that vibrates at a resonant frequency.

In this embodiment, the excitation electrodes 23a, 23b, and 23c are formed to be in aligned regions when the resonator element 2 is viewed in plan view. In addition, in the first piezoelectric substrate 21, at a region nipped between the excitation electrodes 23a and 23b, the thickness-shear vibration as described above is excited. In addition, in the second piezoelectric substrate 22, at a region nipped between the excitation electrodes 23b and 23c, the thickness-shear vibration as described above is excited.

The excitation electrodes 23a, 23b, and 23c and the connection electrodes 24a, 24b, and 24c as described above may be formed of metal materials having high conductivity, such as, aluminum, an aluminum alloy, silver, a silver alloy, chrome, a chrome alloy, or gold.

In addition, as a method of forming such electrodes, various application methods such as sputtering, physical film forming methods such as vacuum deposition, chemical deposition such as CVD, and ink jet methods may be employed.

In addition, the excitation electrode 23b described above has a function of joining the first and second piezoelectric substrates 21 and 22 to each other. For example, with regard to the excitation electrode 23b, a metal material as described above is formed as a film on the upper surface of the second piezoelectric substrate 22, a plasma process or the like is then performed on the film surface to exhibit adhesiveness, and the first piezoelectric substrate 21 is pressure-bonded thereon, thereby joining the first and second piezoelectric substrates 21 and 22 to each other.

Next, the package 3 which accommodates and fixes the resonator element 2 will be described. The package 3 has a substantially rectangular shape in plan view. The package 3 has, as illustrated in FIG. 2, a plate-shaped base substrate 31, a frame-shaped frame member 32, and a plate-shaped cover member 33. The base substrate 31, the frame member 32, and the cover member 33 are stacked in this order from below, and the base substrate 31 and the frame member 32, and the frame member 32 and the cover member 33 are each joined by an adhesive, brazing filler metal, or the like. In addition, the package 3 accommodates the resonator element 2 in an internal space S defined by the base substrate 31, the frame member 32, and the cover member 33. In addition, in FIG. 1, illustration of the cover member 33 is omitted.

It is preferable that the constituent material of the base substrate 31 have insulating property (non-conductive property), and for example, various glass materials, various ceramic materials such as oxide ceramic, nitride ceramic, and carbide-based ceramic, various resin materials such as polyimide, and the like may be used.

In addition, as the constituent materials of the frame member 32 and the cover member 33, for example, the same constituent material as that of the base substrate 31, various metal materials such as Al and Cu, various glass materials, and the like may be used. Particularly, in a case where those having a light transmitting property such as glass materials are used as the constituent material of the cover member 33, when a metallic coating portion (not shown) is formed on the piezoelectric substrate 21 in advance, the metallic coating layer is irradiated with laser via the cover member 33 after the resonator element 2 is accommodated in the package 3 and thus is removed, so that the mass of the piezoelectric substrate 21 is reduced (mass reduction method), thereby adjusting the frequency of the resonator element 2.

As illustrated in FIG. 1 or 2, a pair of mount electrodes 34a and 34b and an electrode 34c are formed on the upper surface of the base substrate 31 so as to be exposed to the internal space S. On the mount electrodes 34a and 34b, epoxy-based or polyimide-based conductive adhesives 39a and 39b containing conductive particles are applied (put), and on the conductive adhesives 39a and 39b, the above-mentioned resonator element 2 is placed. In addition, by hardening the conductive adhesives 39a and 39b, the resonator element 2 is reliably fixed to the mount electrodes 34a and 34b (base substrate 31).

In addition, the fixation is performed by placing the resonator element 2 on the conductive adhesives 39a and 39b so that the conductive adhesive 39a is in contact with the connection electrode 24c of the resonator element 2 and the conductive adhesive 39b is in contact with the connection electrode 24b of the resonator element 2. Accordingly, the left end portion of the resonator element 2 is fixed to the base substrate 31 via the conductive adhesives 39a and 39b, and the connection electrodes 24c and 24b are electrically connected to the mount electrodes 34a and 34b, respectively. In addition, accordingly, the left end portion of the resonator element 2 becomes a “fixed end”, and the right end portion thereof becomes a “free end”. In addition, the resonator element 2 may be fixed to the base substrate 31 in a CSP (Chip Size Package) structure.

In addition, the electrode 34c is electrically connected to the mount electrode 34a via wiring (not shown) and is electrically connected to the connection electrode 24a by, for example, a metallic wire (bonding wire) formed by a wire bonding technique. Accordingly, the excitation electrodes 23a and 23c are electrically short-circuited via the metallic wire, the wiring, the mount electrode 34a, and the connection electrodes 24a and 24c. In the short-circuited configuration, the potentials of the excitation electrodes 23a and 23c can be matched, and thus vibration balance between the first and second piezoelectric substrates 21 and 22 can be easily adjusted. As a result, it is possible to configure a piezoelectric device having a small CI value. In addition, as a conduction method of the excitation electrodes 23a and 23c, in addition to a method using the wire bonding, a method of conducting the connection electrode 24c and the mount electrode 34b using a conductive adhesive may be used, or a conductor for short-circuiting the excitation electrodes 23a and 23c may be plated on the side surfaces of the first and second piezoelectric substrates 21 and 22.

In addition, as illustrated in FIG. 1 or 2, on the lower surface of the base substrate 31, four external terminals 35a, 35b, 35c, and 35d are provided at four corners thereof.

From among the four external terminals 35a to 35d, the external terminals 35a and 35b are hot terminals electrically connected to the mount electrodes 34a and 34b respectively via conductor posts provided in via-holes formed in the base substrate 31. In addition, the other two external terminals 35c and 35d are dummy terminals for enhancing joining strength when the package 3 is mounted on a mounting substrate or uniformizing the distance between the package 3 and the mounting substrate.

The mount electrodes 34a, 34b, the electrode 34c, and the external terminals 35a to 35d may be formed by plating gold on a base layer made by plating, for example, tungsten or nickel.

In addition, in the internal space S of the package 3, an electronic component having a function of driving the resonator element 2 may be mounted (included). The electronic component is, for example, an integrated circuit element (IC) and is joined to the upper surface of the base substrate 31 by an adhesive member such as an insulating (non-conductive) adhesive or an adhesive sheet. In this case, a wiring pattern is formed on the upper surface of the base substrate 31 so as to electrically connect the external terminals 35a and 35b to the mount electrodes 34a, 34b, and the electrode 34c via the electronic component. The piezoelectric device 1 may be configured as a piezoelectric oscillator by forming an oscillation circuit in the electronic component, or the piezoelectric device 1 may be configured as a piezoelectric gyro by forming an angular velocity detection circuit in the electronic component. Alternatively, the electronic component may be provided outside the package 3.

According to the first embodiment as described above, the resonator element 2 have the laminate formed by laminating the plurality of piezoelectric substrates in which thickness-shear vibration occurs, so that the thicknesses of the first and second piezoelectric substrates 21 and 22 can be reduced, and thus displacements of the thickness-shear vibration of the entire resonator element 2 can be increased while suppressing the voltage applied to each of the piezoelectric substrates. Accordingly, the thickness-shear vibration can be effectively excited while suppressing vibration other than the thickness-shear vibration.

### Second Embodiment

Next, a piezoelectric device according to a second embodiment of the invention will be described.

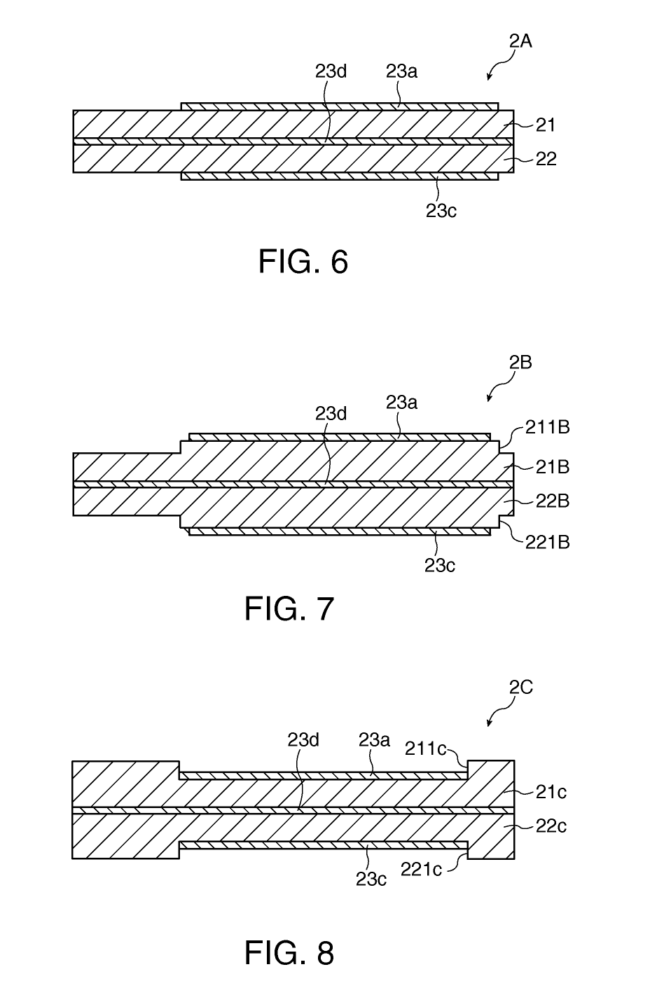

FIG. 6 is a cross-sectional view of a resonator element included in the piezoelectric device according to the second embodiment of the invention.

Hereinafter, differences between the piezoelectric device according to the second embodiment and that according to the above embodiment are mainly described, and description of the same configurations will be omitted.

The piezoelectric device according to the second embodiment is substantially the same as that according to the first embodiment except that the formation range of an electrode layer between first and second piezoelectric substrates is different. In addition, in FIG. 6, illustration of connection electrodes is omitted. In addition, like elements as described in the above embodiment are denoted by like reference numerals.

In a resonator element 2A of the piezoelectric device according to this embodiment, as illustrated in FIG. 6, the first and second piezoelectric substrates 21 and 22 are joined with the excitation electrode 23d interposed therebetween. The excitation electrode 23d is provided to cover the entire lower surface of the first piezoelectric substrate 21 and the entire upper surface of the second piezoelectric substrate 22.

In this embodiment, the excitation electrode 23d is formed to include the excitation electrodes 23a and 23c when the resonator element 2A is viewed in plan view. In addition, in the first piezoelectric substrate 21, at a region nipped between the excitation electrodes 23a and 23d (that is, the formation region of the excitation electrode 23a in plan view), thickness-shear vibration as described above is excited. In addition, in the second piezoelectric substrate 22, at a region nipped between the excitation electrodes 23d and 23c (that is, the formation region of the excitation electrode 23c in plan view), thickness-shear vibration as described above is excited.

The excitation electrode 23d can be easily formed, and positioning thereof with the excitation electrodes 23a and 23c in plan view is not necessary. Accordingly, desired vibration characteristics of the resonator element 2A can be obtained simply and reliably.

In the second embodiment described above, the same effects as those of the first embodiment can be exhibited.

### Third Embodiment

Next, a piezoelectric device according to a third embodiment of the invention will be described.

FIG. 7 is a cross-sectional view of a resonator element included in the piezoelectric device according to the third embodiment of the invention.

Hereinafter, differences between the piezoelectric device according to the third embodiment and those according to the above embodiments are mainly described, and description of the same configurations will be omitted.

The piezoelectric device according to the third embodiment is substantially the same as that according to the first embodiment except that the formation range of an electrode layer between first and second piezoelectric substrates is different and the resonator element has a mesa structure. In addition, the piezoelectric device according to the third embodiment is substantially the same as that according to the second embodiment except that the resonator element has the mesa structure. In addition, in FIG. 7, illustration of connection electrodes is omitted. In addition, like elements as described in the above embodiments are denoted by like reference numerals.

A resonator element 2B of the piezoelectric device according to this embodiment has, as illustrated in FIG. 7, first and second piezoelectric substrates 21B and 22B formed to have the mesa-shaped structure.

On the upper surface of the first piezoelectric substrate 21B, a rectangular convex portion 211B is formed, and on the lower surface of the second piezoelectric substrate 22B, a rectangular convex portion 221B is formed. The convex portions 211B and 221B have rectangular shapes and are formed in aligned regions when the resonator element 2B is viewed in plan view.

The first and second piezoelectric substrates 21B and 22B are joined with the excitation electrode 23d interposed therebetween.

In addition, on the convex portion 211B, the excitation electrode 23a is formed, and on the convex portion 221B, the excitation electrode 23c is formed.

In this embodiment, as thickness-shear vibration is excited in the first and second piezoelectric substrates 21B and 22B, the vibration is trapped by the inside of the convex portions 211B and 221B (mesa structure). Accordingly, the Q value of the thickness-shear vibration is increased. As a result, the CI value can be increased.

In the third embodiment described above, the same effects as those of the first embodiment can be exhibited.

### Fourth Embodiment

Next, a piezoelectric device according to a fourth embodiment of the invention will be described.

FIG. 8 is a cross-sectional view of a resonator element included in the piezoelectric device according to the fourth embodiment of the invention.

Hereinafter, differences between the piezoelectric device according to the fourth embodiment and those according to the above embodiments are mainly described, and description of the same configurations will be omitted.

The piezoelectric device according to the fourth embodiment is substantially the same as that according to the first embodiment except that the formation range of an electrode layer between first and second piezoelectric substrates is different and the resonator element has an inverted-mesa structure. In addition, the piezoelectric device according to the fourth embodiment is substantially the same as that according to the second embodiment except that the resonator element has the inverted-mesa structure. In addition, in FIG. 8, illustration of connection electrodes is omitted. In addition, like elements as described in the above embodiments are denoted by like reference numerals.

A resonator element 2C of the piezoelectric device according to this embodiment has, as illustrated in FIG. 8, first and second piezoelectric substrates 21C and 22C formed to have the inverted-mesa-shaped structure.

On the upper surface of the first piezoelectric substrate 21C, a rectangular concave portion 211C is formed, and on the lower surface of the second piezoelectric substrate 22C, a rectangular concave portion 221C is formed. The concave portions 211C and 221C have rectangular shapes and are formed in aligned regions when the resonator element 2C is viewed in plan view.

The first and second piezoelectric substrates 21C and 22C are joined with the excitation electrode 23d interposed therebetween.

In addition, on the concave portion 211C (on the bottom surface), the excitation electrode 23a is formed, and on the concave portion 221C (on the bottom surface), the excitation electrode 23c is formed.

In this embodiment, as thickness-shear vibration is excited in the first and second piezoelectric substrates 21C and 22C, the vibration is trapped by the inside of the concave portions 211C and 221C (inverted-mesa structure). Accordingly, the Q value of the thickness-shear vibration is increased. As a result, the CI value can be increased.

In the fourth embodiment described above, the same effects as those of the first embodiment can be exhibited.

### Fifth Embodiment

Next, a piezoelectric device according to a fifth embodiment of the invention will be described.

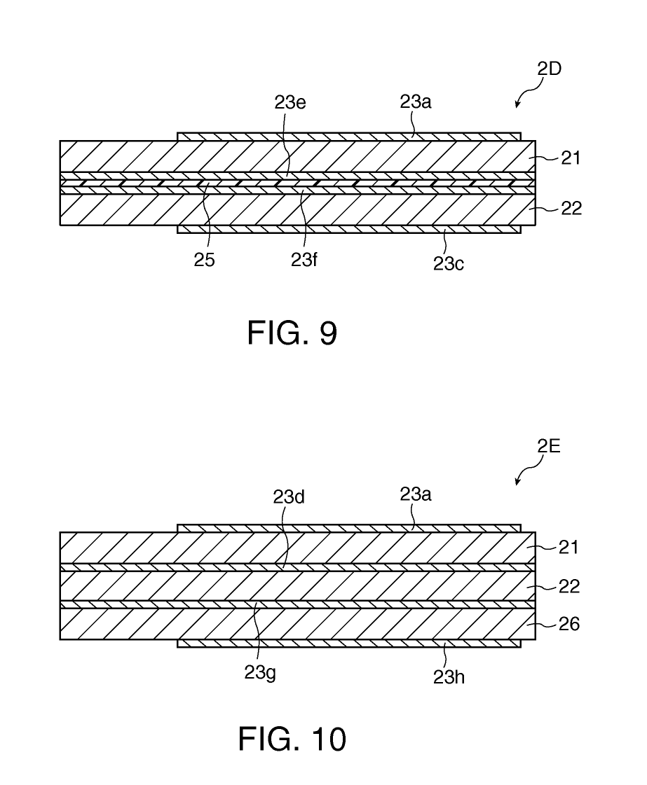

FIG. 9 is a cross-sectional view of a resonator element included in the piezoelectric device according to the fifth embodiment of the invention.

Hereinafter, differences between the piezoelectric device according to the fifth embodiment and those according to the above embodiments are mainly described, and description of the same configurations will be omitted.

The piezoelectric device according to the fifth embodiment is substantially the same as that according to the first embodiment except that a pair of electrode layers and an insulating layer are provided between first and second piezoelectric substrates. In addition, in FIG. 9, illustration of connection electrodes is omitted. In addition, like elements as described in the above embodiments are denoted by like reference numerals.

A resonator element 2D of the piezoelectric device according to this embodiment has, as illustrated in FIG. 9, an excitation electrode 23e formed on the lower surface of the first piezoelectric substrate 21, an excitation electrode 23f formed on the upper surface of the second piezoelectric substrate 22, and an insulating layer 25 provided between the excitation electrodes 23e and 23f.

In this embodiment, the excitation electrodes 23e and 23f are formed to include the excitation electrodes 23a and 23c when the resonator element 2D is viewed in plan view. In addition, in the first piezoelectric substrate 21, at a region nipped between the excitation electrodes 23a and 23e (that is, the formation region of the excitation electrode 23a in plan view), thickness-shear vibration as described above is excited. In addition, in the second piezoelectric substrate 22, at a region nipped between the excitation electrodes 23f and 23c (that is, the formation region of the excitation electrode 23c in plan view), thickness-shear vibration as described above is excited.

Here, the excitation electrodes 23e and 23f are joined with the insulating layer 27 interposed therebetween. Therefore, the resonator D can be configured so that the excitation electrodes 23e and 23f have the reverse polarity. Accordingly, for example, a laminate of the first and second piezoelectric substrates 21 and 22 can be configured by joining the two non-rotation AT plates 100 (see FIGS. 4 and 5) described in the first embodiment.

The constituent material of the insulating layer 25 is not particularly limited as long as the constituent material does not have piezoelectric properties and have insulating properties.

In addition, the thickness of the insulating layer 25 is not particularly limited as long as insulation property between the excitation electrodes 23e and 23f can be ensured. However, in order to reduce the loss of the thickness-shear vibration between the first and second piezoelectric substrates 21 and 22, it is preferable that the insulating layer 25 be formed as thin as possible.

In the fifth embodiment described above, the same effects as those of the first embodiment can be exhibited.

### Sixth Embodiment

Next, a piezoelectric device according to a sixth embodiment of the invention will be described.

FIG. 10 is a cross-sectional view of a resonator element included in the piezoelectric device according to the sixth embodiment of the invention.

Hereinafter, differences between the piezoelectric device according to the sixth embodiment and those according to the above embodiments are mainly described, and description of the same configurations will be omitted.

The piezoelectric device according to the sixth embodiment is substantially the same as that according to the first embodiment except that a third piezoelectric substrate and electrode layers corresponding to this are provided. In addition, in FIG. 10, illustration of connection electrodes is omitted. In addition, like elements as described in the above embodiments are denoted by like reference numerals.

A resonator element 2E of the piezoelectric device according to this embodiment has, as illustrated in FIG. 10, the third piezoelectric substrate 26 joined to the opposite surface of the second piezoelectric substrate 22 to the first piezoelectric substrate 21.

On the upper surface of the third piezoelectric substrate 26, an excitation electrode 23g is formed to cover the entire surface thereof, and the third piezoelectric substrate 26 is joined to the second piezoelectric substrate 22 with the excitation electrode 23g interposed therebetween.

In addition, an excitation electrode 23h is provided on the lower surface of the third piezoelectric substrate 26. The excitation electrode 23h is formed in a region aligned with the excitation electrode 23a when the resonator element F is viewed in plan view.

In this embodiment, as a voltage is applied between the excitation electrodes 23g and 23h, thickness-shear vibration occurs in the third piezoelectric substrate 26 in the same direction as those of the first and second piezoelectric substrates 21 and 22.

Accordingly, the thickness of each of the piezoelectric substrates is further suppressed, thereby further suppressing the voltage applied to each of the piezoelectric substrates or increasing the displacement of the thickness-shear vibration in the entire resonator element 2E. Accordingly, the thickness-shear vibration can be effectively excited while further suppressing vibration other than the thickness-shear vibration.

In the case where the resonator element 2E is formed using the three piezoelectric substrates as described above, when the frequency of the thickness-shear vibration of the resonator element 2E is assumed to be F Hz, three AT plates in which thickness-shear vibration occurs at 3F Hz may be used.

In the sixth embodiment described above, the same effects as those of the first embodiment can be exhibited.

The piezoelectric device as described above can be applied to various electronic devices, and the electronic devices to which the piezoelectric device is applied has high reliability.

The piezoelectric device (piezoelectric resonator) and the electronic device with the piezoelectric device having an electronic component attached according to the invention are not particularly limited, and examples thereof include a personal computer (mobile personal computer), a mobile phone, a digital-still camera, an ink jet ejection apparatus (for example, an ink jet printer), a laptop personal computer, a television, a video camera, a video tape recorder, a car navigation apparatus, a pager, an electronic pocket book (including one with communication capability), an electronic dictionary, a calculator, an electronic game machine, a word processor, a work station, a television phone, a surveillance TV monitor, electronic binoculars, a POS terminal, a medical device (for example, an electronic thermometer, a sphygmomanometer, a glucose meter, an electrocardiogram measuring system, an ultrasonic diagnosis device, and an electronic endoscope), a fish finder, various measurement instruments, various indicators (for example, indicators used in vehicles, airplanes, and ships), a flight simulator, and the like.

While the resonator element, the resonator, and the piezoelectric device according to the invention have been described based on the embodiments, the invention is not limited to the embodiments.

The entire disclosure of Japanese Patent Application No. 2010-092616, filed Apr. 13, 2010 is expressly incorporated by reference herein.

1. A resonator element comprising:
a laminate formed by laminating a plurality of piezoelectric substrates in which thickness-shear vibration occurs.

2. The resonator element according to claim 1, wherein the laminate includes:
a first piezoelectric substrate in which thickness-shear vibration occurs; and
a second piezoelectric substrate which is joined to one surface of the first piezoelectric substrate and in which thickness-shear vibration occurs in the same direction as that of the first piezoelectric substrate.

3. The resonator element according to claim 2, wherein the first and second piezoelectric substrates are configured so that thickness-shear vibration occurs therein in the same direction as a voltage that causes joined surfaces thereof to have the same polarity is applied in thickness directions thereof.

4. The resonator element according to claim 3, wherein the first and second piezoelectric substrates are joined with an electrode layer interposed therebetween.

5. The resonator element according to claim 4, wherein at least one of the first and second piezoelectric substrates is made of a quartz crystal.

6. The resonator element according to claim 4, wherein each of the first and second piezoelectric substrates is made of a quartz crystal.

7. The resonator element according to claim 6, wherein the quartz crystal is a quartz-crystal rotated Y plate.

8. The resonator element according to claim 6, wherein a cut angle of the quartz crystal is any of an AT cut, a BT cut, and an SC cut.

9. The resonator element according to claim 8,
wherein the first and second piezoelectric substrates are made of the quartz crystals having the same cut angle, and
a crystal axis of the second piezoelectric substrate is the same direction as a crystal axis rotated with respect to the first piezoelectric substrate around a Y′ axis or a Z′ axis by 180°.

10. The resonator element according to claim 1, wherein the laminate includes a third piezoelectric substrate which is joined to the opposite surface of the second piezoelectric substrate to that of the first piezoelectric substrate and in which thickness-shear vibration occurs in the same direction as those of the first and second piezoelectric substrates.

11. A resonator comprising:
the resonator element according to claim 1; and
a package which accommodates the resonator element.

12. A piezoelectric device comprising:
the resonator according to claim 11.
